(19) United States
(12) Patent Application Publication
(10) Pub. No.: US 2016/0284892 A1
(43) Pub. Date: Sep. 29, 2016

(54) GLASS FRIT COMPOSITION, PASTE COMPOSITION FOR SOLAR CELL ELECTRODES INCLUDING THE SAME AND SOLAR CELL MODULE

(71) Applicant: LG ELECTRONICS INC., Seoul (KR)

(72) Inventors: Hyeonwoo JANG, Chungju-si (KR); Duckgon KIM, Chungju-si (KR); Ha Chul SONG, Chungju-si (KR)

(73) Assignee: LG ELECTRONICS INC., Seoul (KR)

(21) Appl. No.: 15/035,888

(22) PCT Filed: Nov. 10, 2014
(86) PCT No.: PCT/KR2014/010723

§ 371 Date: May 11, 2016

(30) Foreign Application Priority Data
Nov. 12, 2013 (KR) 10-2013-0136699

(51) Int. Cl. H01L 31/0224; H01L 31/0236; C09D 5/24; C03C 8/10; C03C 8/18; C03C 4/14; H01B 1/16; H01L 31/0216

(52) U.S. Cl. CPC H01L 31/022425; H01B 1/16; H01L 31/02366; H01L 31/02168; C03C 8/10; C03C 8/18; C03C 4/14; C09D 5/24; C03C 2204/00; C03C 2207/10

(57) ABSTRACT

Disclosed is a glass frit composition used for a paste composition for solar cell electrodes containing lead oxide and vanadium oxide, wherein the vanadium oxide is present in an amount of 30 to 70 mol % with respect to 100 mol % in total of the glass frit composition.

### TECHNICAL FIELD

The present invention relates to a glass frit composition, a paste composition for solar cell electrodes comprising the same and a solar cell module.

### BACKGROUND ART

Recently, conventional energy resources such as petroleum and coal are running out and interest in alternative energy sources replacing these resources has thus increased. Among such alternative energy sources, solar cells attract much attention as next-generation cells which convert solar energy into electric energy.

Such a solar cell is manufactured by forming various layers and electrodes according to design. Efficiency of solar cells may be determined according to the design of various layers and electrodes. Low efficiency should be overcome so that solar cells can be put to practical use. Accordingly, solar cell efficiency should be maximized by improving properties of various layers and electrodes.

Various properties, manufacturing cost and the like of electrodes are changed according to properties of glass frits contained in paste compositions for forming electrodes of solar cells. Accordingly, there is a need for development of glass frits capable of improving properties of electrodes and reducing manufacturing costs.

### DISCLOSURE OF INVENTION

### Technical Problem

Therefore, the present invention has been made in view of the above problems, and it is one object of the present invention to provide a glass frit composition, a paste composition for solar cell electrodes comprising the same to reduce cost and improve properties of electrodes.

It is another object of the present invention to provide a solar cell module which is manufactured at low cost and includes electrodes with superior properties.

### Solution to Problem

In accordance with one aspect of the present invention, the above and other objects can be accomplished by the provision of A glass frit composition used for a paste composition for solar cell electrodes including lead oxide and vanadium oxide, wherein the vanadium oxide is present in an amount of 30 to 70 mol % with respect to 100 mol % in total of the glass frit composition.

A total amount of the lead oxide and the vanadium oxide may be 60 to 100 mol % with respect to 100 mol % in total of the glass frit composition.

The total amount of the lead oxide and the vanadium oxide may be 70 to 100 mol % with respect to 100 mol % in total of the glass frit composition.

The lead oxide may be present in an amount of 30 to 70 mol % with respect to 100 mol % in total of the glass frit composition.

The lead oxide may be present in an amount of 30 to 60 mol % and the vanadium oxide may be present in an amount of 40 to 70 mol %with respect to 100 mol % in total of the glass frit composition.

The glass frit composition may further include alkali metal oxide.

The alkali metal oxide may be present in an amount of 1 to 10 mol % with respect to 100 mol % in total of the glass frit composition.

The glass frit composition may have a glass transition temperature of 200 to 300° C.

The glass frit composition may have a crystallization temperature of 280 to 400° C. which is higher than the glass transition temperature.

In accordance with another aspect of the present invention, provided is a paste composition for solar cell electrodes including a conductive powder, a glass frit and an organic vehicle, wherein the glass frit includes lead oxide and vanadium oxide, wherein the vanadium oxide is present in an amount of 30 to 70 mol % with respect to 100 mol % in total of the glass frit.

A total amount of the lead oxide and the vanadium oxide may be 60 to 100 mol % with respect to 100 mol % in total of the glass frit.

The total amount of the lead oxide and the vanadium oxide may be 70 to 100 mol % with respect to 100 mol % in total of the glass frit.

The lead oxide may be present in an amount of 30 to 70 mol % with respect to 100 mol % in total of the glass frit.

The lead oxide may be present in an amount of 30 to 60 mol % and the vanadium oxide may be present in an amount of 40 to 70 mol % with respect to 100 mol % in total of the glass frit.

The glass frit may have a glass transition temperature of 200 to 300° C.

The glass frit may have a crystallization temperature of 280 to 400° C. which is higher than the glass transition temperature.

The glass frit may be present as a powder having a central particle diameter of 3 μm or less and the glass frit may be present in an amount of 0.1 to 5.0 parts by weight with respect to 100 parts by weight in total of the paste composition.

In accordance with another aspect of the present invention, provided is a solar cell module including a photoelectric converter, an electrode connected to the photoelectric converter, and a ribbon adhered to the electrode, wherein the electrode includes a glass frit containing lead oxide and vanadium oxide, the ribbon includes lead and tin, and an adhesion force between the electrode and the ribbon is 1.7N to 6.0N.

The electrode may have a contact resistance of 5 to 40 ohm.cm².

The electrode may include silver as a conductive material.

### BRIEF DESCRIPTION OF DRAWINGS

The above and other objects, features and other advantages of the present invention will be more clearly understood from the following detailed description taken in conjunction with the accompanying drawings, in which:

FIG. 1 is a perspective view illustrating a solar cell module including a solar cell according to one embodiment of the present invention;

FIG. 2 is a sectional view taken along line II-II of FIG. 1;

FIG. 3 is a partial sectional view taken along line III-III of one example of a solar cell in the solar cell module of FIGS. 1; and

FIG. 4 is a partial sectional view taken along line III-III of another example of a solar cell in the solar cell module of FIG. 1.

### MODE FOR THE INVENTION

Reference will now be made in detail to the preferred embodiments of the present invention, examples of which are illustrated in the accompanying drawings. The present invention is not limited to the embodiments and the embodiments may be modified into various forms.

In the drawings, parts unrelated to the description are not illustrated for clear and brief description of the present invention, and the same reference numbers will be used throughout the specification to refer to the same or considerably similar parts. In the drawings, thickness, size or the like is exaggerated or reduced for more clear description. In addition, the size, area or the like of each constituent element is not limited to that illustrated in the drawings.

It will be further understood that, throughout this specification, when one element is referred to as “comprising”another element, the term “comprising” specifies the presence of another element but does not preclude the presence of another element, unless context clearly indicates otherwise. In addition, it will be understood that when one element such as a layer, a film, a region or a plate is referred to as being “on” another element, the one element may be directly on the another element, and one or more intervening elements may also be present. In contrast, when one element such as a layer, a film, a region or a plate is referred to as being “directly on” another element, one or more intervening elements are not present.

Hereinafter, a glass frit composition, a paste composition for solar cell electrodes comprising the same and a solar cell module according to embodiments of the present invention will be described in detail with reference to the annexed drawings. An example of the solar cell module will be first described and the glass frit composition and the paste composition for solar cell electrodes comprising the same will then be described in more detail.

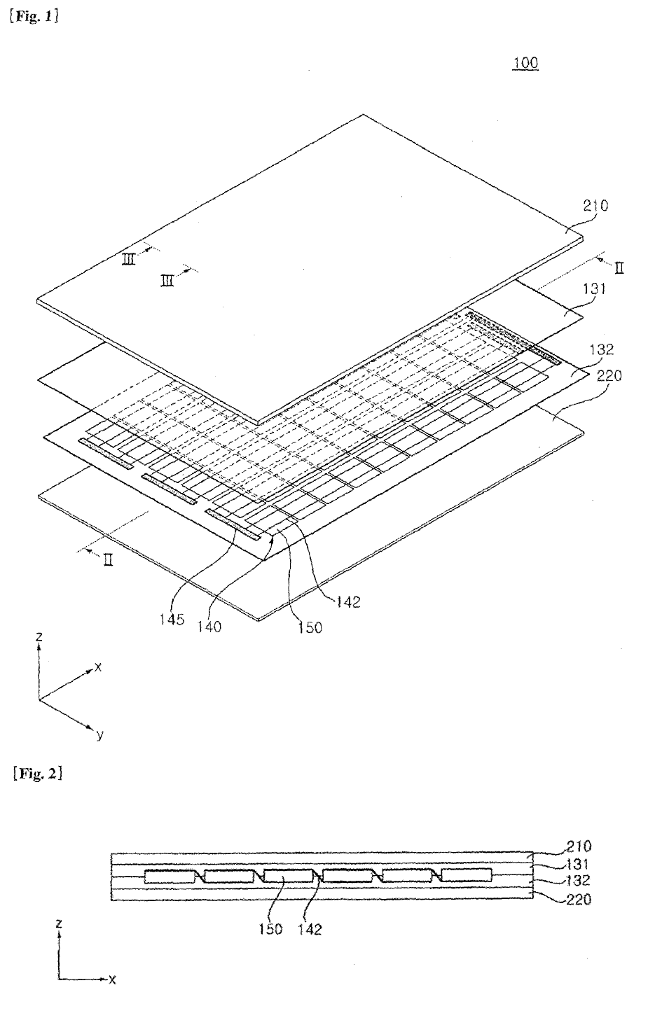

FIG. 1 is a perspective view illustrating a solar cell module including a solar cell according to one embodiment of the present invention and FIG. 2 is a sectional view taken along line II-II of FIG. 1.

Referring to FIGS. 1 and 2, the solar cell module 100 according to one embodiment of the present invention includes a solar cell 150, a front substrate 210 disposed on a front surface of the solar cell 150 and a rear sheet 220 disposed on a rear surface of the solar cell 150. In addition, the solar cell module 100 may include a first sealing material 131 interposed between the solar cell 150 and the front substrate 210, and a second sealing material 132 interposed between the solar cell 150 and the rear sheet 220.

For example, in the present embodiment, a silicon solar cell obtained by forming a p- and/or n-type conductive region on a semiconductor substrate (represented by reference numeral “110” in FIG. 3) made of silicon may be used as the solar cell 150. The silicon solar cell will be described in detail with reference to FIG. 3, but the present invention is not limited to the silicon solar cell. Accordingly, the solar cell 150 may have various structures such as compound semiconductor solar cellstructure, tandemsolar cellstructure and dye-sensitized solar cellstructure.

A plurality of solar cells 150 including the solar cell 150 are electrically connected in series, parallel and series-parallel by a ribbon 142 to constitute a solar cell string 140. For example, as shown in FIG. 2, the ribbon 142 may connect a first electrode (represented by reference numeral “24” in FIG. 3, front electrode) formed on the front surface of one solar cell 150 to a second electrode (represented by reference numeral “34” in FIG. 3, rear electrode) formed on the rear surface of an adjacent solar cell 150 by a tabbing process. The tabbing process may be carried out by applying flux to a surface of the solar cell 150, placing the ribbon 142 on the flux-applied solar cell 150 and performing a firing process. The flux functions to remove an oxide film which interrupts soldering and is not necessarily present.

In addition, a conductive film (not shown) is adhered between one surface of the solar cell 150 and the ribbon 142 and the plural solar cells 150 are connected in series or parallel by thermal compression. The conductive film (not shown) may have a structure in which conductive particles comprising gold, silver, nickel, copper or the like, each having superior conductivity, are dispersed in a film made of an epoxy resin, an acrylic resin, a polyimide resin, a polycarbonate resin or the like. When such a conductive film is compressed while heat is applied thereto, the conductive particles are exposed to the outside of the film and the solar cell 150 is electrically connected to the ribbon 142 through the exposed conductive particles. In the case in which modularization is performed by connecting the solar cells 150 through the conductive film(not shown), process temperature is decreased and bending of the solar cells 150 is thus prevented.

In addition, the bus ribbon 145 alternately connects both ends of the ribbons 142 of the solar cell strings 140 and thereby electrically connects the solar cell strings 140. The bus ribbon 145 may be disposed in a direction crossing a length direction of the solar cell string 140 at the end of the solar cell string 140. Such a bus ribbon 145 is connected to a junction box (not shown) which collects electricity generated by the solar cell 150 and prevents backflow of electricity.

The first sealing material 131 is disposed on a light-receiving surface of the solar cell 150, while the second sealing material 132 is disposed on the rear surface of the solar cell 150. The first sealing material 131 and the second sealing material 132 are adhered to each other by lamination, thereby blocking moisture or oxygen which may have negative effects on the solar cell 150 and enabling chemical bonding between respective elements of the solar cell.

The first sealing material 131 and the second sealing material 132 may contain an ethylene vinyl acetate(EVA) copolymer resin, a polyvinyl butyral resin, a silicone resin, an ester resin, an olefin resin or the like.

However, the present invention is not limited to the formation method of the first and second sealing materials 131 and 132. Accordingly, the first and second sealing materials 131 and 132 may be formed by a method other than lamination using various materials.

The front substrate 210 is disposed on the first sealing material 131 such that sunlight passes therethrough, and is preferably a reinforced glass so as to protect the solar cell 150 from external shocks or the like. In addition, the front substrate 210 is more preferably a low iron reinforced glass containing a small amount of iron so as to prevent reflection of sunlight and improve transmission of sunlight.

The rear sheet 220 is a layer which protects the solar cell 150 at the rear surface thereof and has waterproofing, insulation and UV blocking functions. The rear sheet 220 may be a Tedlar/PET/Tedlar (TPT)sheet, but the present invention is not limited thereto. In addition, the rear sheet 220 may be made of a material having superior reflectivity so as to reflect sunlight emitted from the front substrate 210 and reuse the same. However, the present invention is not limited in terms of material and the rear sheet 220 may be made of any transparent material which admits incident sunlight and thus implements a bi-facial solar cell module 100.

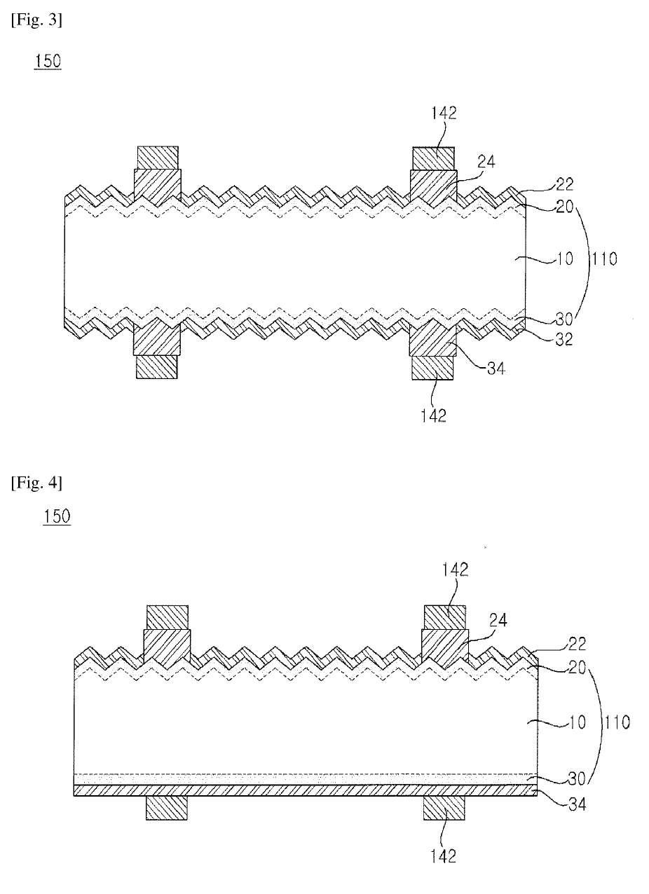

Hereinafter, various structures of the solar cell 150 will be described in detail with reference to FIGS. 3 and 4. FIGS. 3 and 4 show only as an example of various structures of the solar cell 150 and structures of the solar cell 150 may be changed.

FIG. 3 is a partial sectional view taken along line III-III of an example of a solar cell in the solar cell module of FIG. 1.

Referring to FIG. 3, the solar cell 150 according to the present embodiment includes a substrate 110 (for example, a semiconductor substrate, hereinafter, referred to as a “semiconductor substrate”), conductive regions 20 and 30 formed on the semi-conductor substrate 110, and electrodes 24 and 34 electrically connected to the conductive regions 20 and 30, respectively. The conductive regions 20 and 30 may include an emitter region 20 and a rear electric field region 30, and the electrodes 24 and 34 may include a first electrode 24 electrically connected to the emitter region 20 and a second electrode 34 electrically connected to the rear electric field region 30. The solar cell 150 may further include an anti-reflective film 22, a passivation film 32 and the like. The ribbon 142 enabling connection to another solar cell 150 is disposed on the electrodes 24 and 34. This will be described in more detail.

The semiconductor substrate 110 includes regions where the conductive regions 20 and 30 are formed, and a base region 10 which is a region where the conductive regions 20 and 30 are not formed. The base region 10 may comprise, for example, silicon containing a first conductive type dopant. The silicon may be monocrystalline silicon or polycrystalline silicon, and the first conductive type dopant is for example n-type or p-type. That is, the base region 10 may be formed of monocrystalline or polycrystallinesilicon doped with a Group V element such as phosphorus (P), arsenic (As), bismuth (Bi) or antimony (Sb). Alternatively, the base region 10 may be formed of monocrystalline or polycrystalline silicon doped with a Group III element such as boron (B), aluminum (Al), gallium (Ga) or indium (In). For example, in the present embodiment, the base region 10 may be n-type.

The front and rear surfaces of the semiconductor substrate 110 may have irregularities formed by texturing. The irregularities formed by texturing are, for example, formed along a specific surface (for example, in the case of silicon, surface (111)) of a semiconductor constituting the semiconductor substrate 110. As a result, the irregularities formed by texturing may have, for example, a pyramidal shape.

The irregularities formed on the front and rear surfaces of the semiconductor substrate 110 by texturing increase surface roughness and thereby reduce reflection of light incident through the front and rear surfaces of the semiconductor substrate 110. Accordingly, an amount of light which reaches p-n junction formed at the boundary between the semiconductor substrate 110 and the emitter region 20 is increased and light loss is thus minimized.

The emitter region 20 comprising a second conductive type dopant may be formed on the front surface of the semiconductor substrate 110. In the present embodiment, the emitter region 20 has a second conductive type dopant opposite to the semiconductor substrate 110. Specific examples of the Group III or V elements have been described with respect to the semiconductor substrate 110 and explanation thereof is thus omitted.

The present drawing illustrates that the emitter region 20 has a structure in which a doping concentration of the second conductive type dopant is entirely homogeneous. However, the present invention is not limited to this structure and the emitter region 20 may be doped so as to have a selective structure including a high-concentration doping region and a low-concentration doping region. Other variations in structure are possible.

The anti-reflective film 22 and the first electrode 24 are formed on the semiconductor substrate 110, more specifically, on the emitter region 20 formed on the semiconductor substrate 110.

The anti-reflective film 22 may be formed substantially over the entire front surface of the semiconductor substrate 110, excluding the region corresponding to the first electrode 24. The anti-reflective film 22 reduces reflection of light incident upon the front surface of the semiconductor substrate 110 and passivates defects present on the surface or in the bulk of the emitter region 20.

By reducing reflection of light incident upon the front surface of the semiconductor substrate 110, an amount of light which reaches the p-n junction formed at the boundary between the semiconductor substrate 110 and the emitter region 20 is increased. Accordingly, short-circuit current (Isc) of the solar cell 150 is increased. In addition, defects present in the emitter region 20 are passivated, recombination sites of minority carriers are removed and open-circuit voltage (Voc) of the solar cell 150 is thus increased. As such, open-circuit voltage and short-circuit current of the solar cell 150 can be increased by the anti-reflective film 22 and efficiency of the solar cell 150 is thus increased.

The anti-reflective film 22 may be formed of various materials. For example, the anti-reflective film 22 may have a single film structure including one selected from the group consisting of a siliconnitride film, a silicon nitride film containing hydrogen, a siliconoxide film, a siliconoxidenitride film, an aluminumoxide film, MgF₂, ZnS, TiO₂ and CeO₂, or a multi-film structure including two or more thereof. However, the present invention is not limited to the structure of the anti-reflective film 22 and the anti-reflective film 22 may comprise various materials. A separate front passivation film (not shown) for passivation may be further provided between the semiconductor substrate 110 and the anti-reflective film 22. This also falls within the scope of the present invention.

The first electrode 24 is electrically connected to the emitter region 20 through an opening formed in the anti-reflective film 22 (that is, while passing through the anti-reflective film 22). The first electrode 24 may be formed in various shapes using various materials. For example, the second electrode 24 includes a plurality of finger electrodes disposed in parallel and at least one bus bar electrode to connect the finger electrodes.

A rear electric field region 30 comprising a first conductive type dopant in a higher doping concentration than the semiconductor substrate 110 is formed on the rear surface of the semiconductor substrate 110. The present drawing illustrates that the rear electric field region 30 has a structure in which a doping concentration of the first conductive type dopant is entirely homogeneous. However, the present invention is not limited to this structure and the electric field layer 30 may have a selective structure including a high-concentration doping region and a low-concentration doping region. Other variations in structure are possible.

The passivation film 32 and the second electrode 34 may be formed on the rear surface of the semiconductor substrate 110. As described above, the solar cell 150 according to the present embodiment is an n-type solar cell wherein the base region 10 is n-type and the second electrode 34 has a similar structure to the first electrode 24. That is, the second electrode 34 may be formed in a predetermined pattern. For example, the second electrode 34 includes a plurality of finger electrodes and at least one bus bar electrode connecting the same. As a result, the solar cell 150 may have a bi-facial structure in which the solar cell 150 also uses light incident upon the rear surface.

The passivation film 32 may be formed substantially over the entire rear surface of the semiconductor substrate 110, excluding the region where the second electrode 34 is formed. The passivation film 32 passivates defects present on the rear surface of the semiconductor substrate 110 and thereby removes recombination sites of minority carriers. As a result, open-circuit voltage of the solar cell 150 is increased.

For example, the passivation film 32 may have a single film structure including one selected from the group consisting of a silicon nitride film, a silicon nitride film containing hydrogen, a silicon oxide film, a silicon oxide nitride film, an aluminum oxide film, MgF2, ZnS, TiO2 and CeO2, or a multi-film structure including two or more thereof. However, the present invention is not limited in terms of the structure of the passivation film 32 and the passivation film 32 may comprise various materials.

The second electrode 34 is electrically connected to the rear electric field region 30 through an opening formed in the passivation film 32 (that is, while passing through the passivation film 32). The second electrode 34 may be formed in various shapes using various materials.

The ribbon 142 connected to the second electrode 34 of an adjacent another solar cell 150 is disposed on the first electrode 24 and the ribbon 142 connected to the first electrode 24 of the adjacent another solar cell 150 is disposed on the second electrode 34. The ribbon 142 may be adhered to the first or second electrode 24 or 34 by soldering.

In this case, the first and second electrodes 24 and 34 may be, for example, formed by applying a paste composition comprising a conductive material, followed by firing. The first and second electrodes 24 and 34 may be formed by a fire-through process using the paste composition according to the embodiment of the present invention described later.

FIG. 4 is a partial sectional view taken along line III-III of another example of a solar cell in the solar cell module of FIG. 1. A detailed explanation of contents of the solar cell shown in FIG. 4 that are the same as or extremely similar to those of the solar cell shown in FIG. 3 is omitted.

Referring to FIG. 4, in the present embodiment, a passivation film (represented by reference numeral “32” in FIG. 3) is not formed on the rear surface of the semi-conductor substrate 110 and the second electrode 34 is entirely formed on the rear surface of the semiconductor substrate 110. Such a second electrode 34 may be formed by applying a paste composition onto the rear surface of the semiconductor substrate 110 and firing the composition, without the fire-through process.

The solar cell 150 according to the present embodiment may be a p-type solar cell in which the base region 10 and the rear electric field region 30 are p-type and the emitter region 20 is n-type. The rear electric field region 30 may be formed of the dopant (for example, aluminum) contained in the paste composition which is diffused during firing of the paste composition for forming the second electrode 34. As a result, the rear electric field region 30 is formed in the process of firing for forming the second electrode 34 without an additional process, thus simplifying the overall manufacturing process.

In the present embodiment, the first electrode 24 may be formed by a fire-through process using the paste composition according to the embodiment of the present invention as shown in FIG. 3. The second electrode 34 may be formed using a paste comprising a conductive material (for example, aluminum) different from the paste composition according to the present embodiment.

Hereinafter, the paste composition and the glass frit composition contained therein used for forming the first and second electrodes 24 and 34 of the n-type solar cell and the first electrode 24 (hereinafter, referred to as “electrodes 24 and 34”) of the p-type solar cell will be described in detail.

The paste composition according to the present invention comprises a conductive powder, a glass frit composition (hereinafter, referred to as a “glass frit”) and an organic vehicle and optionally further comprises at least one other additive or the like. The paste composition according to the present invention is printed on the anti-reflective film 22 or the passivation film 32 and is then fired. During firing, the paste composition etches the anti-reflective film 22 or the passivation film 32, thus enabling electrical connection to the emitter region 20 or the rear electric field region 30 formed on the semiconductor substrate 110 through the anti-reflective film 22 or the passivation film 32. A process for electrical connection to the emitter region 20 or the rear electric field region 30 through the anti-reflective film 22 or the passivation film 32 is referred to as the fire-through process. The paste composition according to the present invention will be described in more detail.

The conductive powder may comprise a metal, a conductive polymer or the like. The metal may be silver, aluminum, gold, copper, or an alloy thereof. The conductive polymer may be polypyrrole, polyaniline or the like. As the conductive powder, silver having high electrical conductivity and superior adhesion to the ribbon 142 may be used.

In the present embodiment, the conductive powder may be present in an amount of 50 to 90 parts by weight, with respect to 100 parts by weight in total of the paste composition. When the conductive powder is present in an amount of less than 50 parts by weight, electrical properties may be bad due to low content of conductive material in the paste composition. When the conductive powder is present in an amount exceeding 90 parts by weight, the glass frit and the organic vehicle are not sufficiently contained, adhesion between the electrodes and the semiconductor substrate 110 is deteriorated and contact resistance of the electrodes may be bad, but the present invention is not limited thereto and parts by weight of the conductive powder may be changed.

The conductive powder may have various shapes such as a spherical or non-spherical shape (for example, plate, bell or flake shapes). The conductive powder may be one type of particles or a combination of particles having different particle sizes.

In the present embodiment, the glass frit comprises lead oxide (PbO) and vanadium oxide (V₂O₅), thus efficiently decreasing glass transition temperature (Tg).

The lead oxide etches the anti-reflective film 22 or the passivation film 32, thus facilitating formation of a fire-through passing through the anti-reflective film 22 or the passivation film 32 and providing superior contact with the semiconductor substrate 110. In addition, lead oxide improves conductivity of the electrodes 24 and 34 after firing due to high solid solubility of conductive material(for example, silver). For example, lead oxide has higher solid solubility of silver than bismuth oxide.

In addition, vanadium oxide functions to decrease glass transition temperature of the glass frit, to enhance glass strength and thereby to improve adhesion to the ribbon 142. When the glass transition temperature is decreased, glass frit has a sufficient flowability during firing, providing even and homogeneous contact between the semi-conductor substrate 110 and the electrodes 24 and 34. In addition, decrease in firing temperature resulting from decrease in glass transition temperature can reduce process costs. Tellurium oxide conventionally added to decrease glass transition temperature is expensive (several times the price of vanadium oxide) and low strength upon formation of glass, while vanadium oxide according to the present embodiment is cheap and has high strength during formation of glass as compared totellurium oxide, thus providing superior adhesion to the ribbon 142.

As such, when the glass frit comprises vanadium oxide and lead oxide, costs are reduced, contact with the semiconductor substrate 110 is improved, and adhesion to the ribbon 142 is thus enhanced.

In this case, a total amount of lead oxide and vanadium oxide may be 60 to 100 mol % with respect to 100 mol % of the glass frit. By adjusting the total amount of lead oxide and vanadium oxide to 60 mol % or more, effects obtained by the lead oxide and vanadium oxide can be sufficiently implemented.

The combination of lead oxide and vanadium oxide may be the main component of the glass frit. “The main component” means that lead oxide and vanadium oxide have a content of 50 mol % or more in total. As a result, effects obtained by lead oxide and vanadium oxide can be further improved. The effects can be greatly improved by adjusting the total amount of lead oxide and vanadium oxide to 70 to 100 mol % with respect to 100 mol % in total of the glass frit, and the effects can be maximized by adjusting the total amount to 80 to 100 mol %. When glass frit is composed of only lead oxide and vanadium oxide, raw materials of the glass frit are simplified and properties of glass frit are improved.

For example, lead oxide may be present in an amount of 30 to 70 mol % (more specifically, 30 to 70 mol %) with respect to 100 mol % in total of the glass frit. When the lead oxide is present in an amount lower than 30 mol %, the fire-through process may not be smoothly performed and contact between the semiconductor substrate 110 and the electrodes 24 and 34 may not be excellent. When the lead oxide is present in an amount higher than 70 mol %, the glass transition temperature of glass frit cannot be reduced, glass formation capability is deteriorated, flowability of the glass frit during firing is deteriorated and adhesion between the electrodes and the ribbon is thus deteriorated. For more advantageous effects, lead oxide may be present in an amount of 60 mol % or less.

In addition, vanadium oxide may be present in an amount of 30 to 70 mol % (more specifically, 40 to 70 mol %) with respect to 100 mol % in total of the glass frit. When the vanadium oxide is present in an amount less than 30 mol %, the glass transition temperature of glass frit may not be sufficiently decreased and adhesion between the electrodes and the ribbon may be deteriorated. When vanadium oxide is present in an amount higher than 70 mol %, the fire-through process may not be smoothly performed due to insufficient amount of lead oxide and contact between the semiconductor substrate 110 and the electrodes 24 and 34 may not be excellent. For more advantageous effects, vanadium oxide may be present in an amount of 40 mol % or more.

In the present embodiment, the glass frit may further comprise alkali metal oxide in addition to lead oxide and vanadium oxide. For example, alkali metal oxide comprises Li₂O, Na₂O, K₂O or the like. Alkali metal oxide controls the glass transition temperature and crystallization temperature of the glass frit. That is, glass transition temperature and crystallization temperature of glass frit can be reduced by further adding alkali metal oxide. For this reason, properties of the paste composition for electrodes of the solar cell 150 can be improved by controlling difference between glass transition temperature and crystallization temperature of glass frit. That is, the gap between the glass transition temperature and crystallization temperature of glass frit is relatively small, so that the paste composition is crystallized immediately after glassification during firing of the paste composition and firing can be thus complete within a short time.

For example, the alkali metal oxide may be present in an amount of 1 to 20 mol %, for example, 1 to 10 mol %. When the alkali metal oxide is present in an amount less than 1 mol %, effects obtained by the alkali metal oxide may not be sufficiently exerted. When alkali metal oxide is present in an amount higher than 20 mol %, glass formation capability of glass frit may be deteriorated. The alkali metal oxide may be present in an amount of 10 mol % or less so as to sufficiently obtain glass formation capability of glass frit.

The lead oxide, vanadium oxide and/or alkali metal oxide may be composed of oxygen polyhedron having a network structure containing oxygen (for example, a random network structure).

In addition, the glass frit may further comprise an additional glassy or crystalline inorganic substance in addition to the oxide forming the network structure. The glassy or crystalline inorganic substance may be selected from various known substances and a detailed explanation thereof is thus omitted.

The glass frit according to the present embodiment may have a glass transition temperature of 200 to 300° C. When the glass transition temperature of the glass frit is less than 200° C., the glass frit is readily crystallized and may not maintain a glass state. As a result, flowability in the paste composition during firing is deteriorated and the electrodes 24 and 34 may not evenly and homogeneously contact the semiconductor substrate 110. When the glass transition temperature of glass frit exceeds 300° C., the electrodes 24 and 34 may not evenly and homogeneously contact the semiconductor substrate 110 due to low flowability of the glass frit, glass strength of glass frit may be deteriorated due to relatively low content of vanadium oxide and adhesion to the ribbon 142 may be thus deteriorated. When taking into consideration the fact that conventional lead oxide-based glass frits have a glass transition temperature higher than 300° C., it can be seen that the glass frits according to the present invention contain a sufficient amount of vanadium oxide, thus effectively reducing the glass transition temperature.

In addition, the crystallization temperature of glass frit is higher than the glass transition temperature thereof and is 280 to 400° C. When the crystallization temperature is lower than 280° C., the glass state may not be maintained due to small difference between the crystallization temperature and the glass transition temperature. When the crystallization temperature is higher than 400° C., crystallization is not efficiently performed after glassification due to increased crystallization temperature, thus requiring a long firing time.

However, the present invention is not limited to this crystallization temperature range and the glass transition temperature and crystallization temperature of the glass frit may be changed.

The glass frit may be formed by mixing powders of substances (for example, lead oxide, vanadium oxide, and/or alkali metal oxide, other glassy and crystalline inorganic substances and the like)constituting the glass frit, melting the mixture, cooling the melted substance into a predetermined shape and grinding the resulting substance. For example, the powders of substances constituting glass frit are mixed and melted at a temperature of 1,000 to 1,300° C., and the melted substance is dropped in a droplet form and passes between two rolls to prepare a plate-type glass frit which is then ground.

The glass frits thus prepared may have a central particle diameter (D50) of 3 μm or less (for example, 0.5 μm to 3 μm), for example, a central particle diameter of 0.5 μm to 2 μm(more specifically 0.5 μm to 1.7 μm). Manufacturing of glass frit having a central particle diameter less than 0.5 μm may be impossible. If possible, glass frit having a central particle diameter less than 0.5 μm may also be used. When the central particle diameter of glass frit is greater than 3 μm, the glass frit is not easily glassified during firing due to increased maximum particle diameter of glass frit and flowability is thus bad. In order to further improve properties of the glass frit and the paste composition comprising the same, the central particle diameter of the glass frit may be adjusted to 2 μm or less, more specifically, 1.7 μm or less, but the present invention is not limited thereto and various modifications are possible.

The glass frit may be present in an amount of 0.1 to 5 parts by weight, with respect to 100 parts by weight in total of the paste composition. Within the range of 0.1 to 5 parts by weight, the glass frit improves adhesive strength, ease of sintering and post-processing properties of the solar cell 150.

The organic vehicle may be obtained by dissolving a binder in a solvent and may further comprise a defoaming agent, a dispersant or the like. The solvent may be an organic solvent such as terpineol or carbitol. The binder may be a cellulose binder.

The organic vehicle may be present in an amount of 2 to 20 parts by weight, with respect to 100 parts by weight in total of the paste composition. When the organic vehicle is present in an amount of less than 2 parts by weight, an amount of the conductive powder is relatively great and cost of the paste composition is increased. When the organic vehicle is present in an amount exceeding 20 parts by weight, electrical conductivity of the first and second electrodes 24 and 34 may be decreased. However, the present invention is not limited to the amount of the organic vehicle and the amount of the organic vehicle may be changed according to amounts of the glass frit and the conductive powder.

The paste composition may further comprise a dispersant, a thixotropic agent, a leveling agent, a defoaming agent or the like as other additives. The dispersant may comprise a variety of substances to improve dispersability of the conductive powder, glass frit and the like. The thixotropic agent may be a polymer/organic substance such as urea, amide or urethane, inorganic silica, or the like. The leveling agent, the defoaming agent and the like may be selected from known substances. Such an additive may be present in an amount of 0.1 to 5 parts by weight. When the additive is present in an amount less than 0.1 parts by weight, effects of the additive may not be sufficiently obtained and when the additive is present in an amount higher than 5 parts by weight, the content of conductive powder may be decreased due to excessively high amount thereof.

The paste composition may be prepared by the following method.

A binder is dissolved in a solvent and pre-mixing is performed to prepare an organic vehicle. A conductive powder, a glass frit and an additive are added to the organic vehicle and the resulting mixture is aged for a predetermined time. The aged mixture is mechanically mixed and dispersed using a 3-roll mill or the like. The mixture is filtered and defoamed to prepare a paste composition. This method is provided only as an example and the present invention is not limited to the method.

The prepared paste composition is applied to a semiconductor substrate 110 by various methods (for example, screen printing), followed by firing, to form electrodes 24 and 34 connected to the conductive regions 20 and 30 by fire through.

Regarding the paste composition according to the present embodiment, the glass frit contains predetermined contents or more of lead oxide and vanadium oxide. As a result, the glass frit contains a sufficient amount of lead oxide, thus providing smooth performance of fire through and maintaining excellent contact between the electrodes 24 and 34 and the semiconductor substrate 110 after firing. In addition, the glass frit contains a sufficient amount of vanadium oxide, thus decreasing glass transition temperature, reducing process costs, improving flowability and glass strength during firing and thereby increasing adhesion to the ribbon 142. In particular, vanadium oxide sufficiently provides the effects described above and is cheap, thus improving properties of glass frit and greatly reducing manufacturing costs.

For example, the electrodes 24 and 34 which are manufactured using the paste composition according to the present embodiment and contain silver as a conductive powder may have a low contact resistance. For example, when the semiconductor substrate 10 has a sheet resistance of 85 ohm and a contact resistance, contact resistance measured by a contact resistance tester (for example, Core scan™ available from Sun Lab) may be 5 to 40 ohm.cm² (for example, 5 to 25 ohm.cm²). In this case, the semiconductor substrate 10 may have a current density (Jsc) of 30 mA/cm². In addition, adhesion force between the electrodes 24 and 34 and the ribbon 142 may be high. For example, under the conditions that a printing amount of the electrodes 24 and 34 is 0.015 to 0.020 g/cm², an adhesion temperature at which the electrodes 24 and 34 are adhered to the ribbon 142 is 300 to 380° C., adhesion time is 1.5 to 2 seconds, after the electrodes 24 and 34 are adhered to the ribbon 142 and an adhesion force is then measured using an adhesion force tester (for example, Micro TXA™ available from Chemi Lab). In this case, the adhesion force is 1.7N to 6.0N(for example, 2.5N to 6.0N),In the adhesion force tester, a detachment velocity of the ribbon 142 is 3 to 5 mm/sec, and a measurement angle (an angle at which the ribbon 142 is drawn) is 90 to 180 degrees, but the present invention is not limited thereto, and contact resistance, adhesion force, methods for measuring the same and the like may be changed.

Hereinafter, the present invention will be described in more detail with reference to the following examples. However, the examples are provided only for illustration of the present invention and are not to be construed as limiting the scope of the present invention.

### Example 1

30 mol % of a lead oxide (PbO) powder was mixed with 70 mol % of a vanadium oxide (V₂O₅) powder, the resulting mixture was melted at a temperature of 1,200° C., the resulting product was dropped in a droplet form and passed between two rolls to obtain a plate-shaped product. The product was ground to produce a glass frit having a central particle diameter of 1 μm.

0.5 parts by weight of EC300.8 (binder) available from Dow Chemical Company was dissolved in 8 parts by weight of butyl carbitol (solvent), with respect to 100 parts by weight in total, to prepare an organic vehicle. 86 parts by weight of a silver powder (conductive powder), 3.5 parts by weight of the glass frit, and 2 parts by weight of BYK-111.8 available from BYK Co., Ltd. were added to the organic vehicle, followed by mixing. The resulting mixture was aged for 12 hours and was then secondarily mixed and dispersed using a 3-roll mill. The dispersion was filtered and defoamed to prepare a paste composition.

### Example 2

A glass frit was produced in the same manner as in Example 1, except that 40 mol % of a lead oxide powder and 60 mol % of a vanadium oxide powder were used. A paste composition was prepared in the same manner as in Example 1 using the glass frit thus produced.

### Example 3

A glass frit was produced in the same manner as in Example 1, except that 50 mol % of a lead oxide powder and 50 mol % of a vanadium oxide powder were used. A paste composition was prepared in the same manner as in Example 1 using the glass frit thus produced.

### Comparative Example 1

A glass frit was produced in the same manner as in Example 1, except that 25 mol % of a lead oxide powder and 75 mol % of a vanadium oxide powder were used. A paste composition was prepared in the same manner as in Example 1 using the glass frit thus produced.

### Comparative Example 2

A glass frit was produced in the same manner as in Example 1, except that 80 mol % of a lead oxide powder and 20 mol % of a vanadium oxide powder were used. A paste composition was prepared in the same manner as in Example 1 using the glass frit thus produced.

### Comparative Example 3

A glass frit was produced in the same manner as in Example 1, except that 61 mol % of a lead oxide powder, 18.31 mol % of silicon oxide (Sift) and 20.70 mol % of a bismuth oxide powder were used. A paste composition was prepared in the same manner as in Example 1 using the glass frit thus produced.

### Comparative Example 4

A glass frit was produced in the same manner as in Example 1, except that 56.75 mol % of a lead oxide powder, 20.93 mol % of silicon oxide, and 22.32 mol % of a bismuth oxide powder were used. A paste composition was prepared in the same manner as in Example 1 using the glass frit thus produced.

### Comparative Example 5

A glass frit was produced in the same manner as in Example 1, except that 53.06 mol % of a lead oxide powder, 25.40 mol % of silicon oxide, and 21.54 mol % of a bismuth oxide powder were used. A paste composition was prepared in the same manner as in Example 1 using the glass frit thus produced.

### Comparative Example 6

A glass frit was produced in the same manner as in Example 1, except that 40 mol % of a lead oxide powder and 60 mol % of tellurium oxide (TeO₂) were used. A paste composition was prepared in the same manner as in Example 1 using the glass frit thus produced.

Glass transition temperatures of glass frits according to Examples 1 to 3 and Comparative Examples 1 to 6 were measured. Paste compositions according to Examples 1 to 3, and Comparative Examples 1 to 6 were applied to a nitride film formed on the semiconductor substrate by printing, followed by firing. Then, whether or not the glass frit composition etched the nitride film was determined.

In addition, contact resistances of electrodes and semiconductor substrates formed by applying paste compositions according to Examples 1 to 3 and Comparative Examples 1 to 6 to the semiconductor substrate and then firing the same were measured. At this time, the contact resistance was measured using a contact resistance tester (for example, Core scan™ available from Sun Lab) under conditions that the semi-conductor substrate had a sheet resistance of 85 ohm and a current density(Jsc) of 30 mA/cm².

In addition, the paste compositions according to Examples 1 to 3 and Comparative Examples 1 to 6 were applied in an amount of 0.020 g/cm² and fired to form electrodes. A ribbon containing 60 mol % of Sn and 40 mol % of Pb was tabbed on the electrode at an adhesion temperature of 340° C. for an adhesion time of 2 seconds, adhesion force between the electrode and the ribbon was measured using an adhesion force tester at a rate of 5 mm/sec while the ribbon was detached by drawing at a measurement angle of 180 degrees. The adhesion force tester used herein was a Micro TXA™ available from Chemi Lab.

Table 1

TABLE 1

| | Glass | Nitride | | |
|---|---|---|---|---|
| | transition | film | Contact | Adhesion |
| | temperature | etching | resistance | force |
| | [° C.] | property | [ohm · cm²] | [N] |
| Example 1 | 235 | Good | 39.9 | 1.7 |
| Example 2 | 247 | Good | 24.6 | 2.7 |
| Example 3 | 262 | Good | 29.1 | 3.3 |
| Comparative | 226 | Bad | — | — |
| Example 1 | | | | |
| Comparative | Crystallization | Good | — | — |
| Example 2 | (impossible | | | |
| | glassification) | | | |
| Comparative | 328 | Good | 43.8 | 3.0 |
| Example 3 | | | | |
| Comparative | 348 | Good | 46.8 | 2.2 |
| Example 4 | | | | |
| Comparative | 368 | Good | 58.2 | 1.6 |
| Example 5 | | | | |
| Comparative | 237 | Good | 26.7 | 0.6 |
| Example 6 | | | | |

As can be seen from Table 1, glass frits according to Example 1 to 3 can sufficiently etch the nitride film due to sufficient contents of lead oxide and vanadium oxide and are sufficiently glassified at a firing temperature due to low glass transition temperature, thus bringing the electrode in contact with the semiconductor substrate so that the electrode has uniform and superior properties. As a result, low contact resistance of 40 ohm . cm² and high adhesion force of 1.7N or more can be obtained.

On the other hand, the glass frit according to Comparative Example 1 does not sufficiently etch the nitride film due to insufficient content of lead oxide, thus not providing efficient contact with the semiconductor substrate. The glass frit according to Comparative Example 2 may not be glassified by crystallization due to insufficient content of vanadium oxide.

In addition, glass frits according to Comparative Examples 3 to 5 have higher glass transition temperatures and thus higher contact resistances than those of Examples 1 to 3.

In addition, the glass frit according to Comparative Example 6 has a glass transition temperature comparable to the glass frit according to the present Example, but a considerably low adhesion force to the ribbon of 0.6N. In addition, the glass frit according to Comparative Example 6 contains tellurium oxide and thus has a high price that is several times that of vanadium oxide of the glass frits according to Examples 1 to 3. As a result, manufacturing cost of the glass frit according to Comparative Example 6 is greatly increased.

Examples 1 to 3 containing lead oxide and vanadium oxide without containing other substances have superior properties to Comparative Examples 1 to 6. Superior contact resistance and adhesion force values can be obtained through use of the alkali metal oxide or the like, and further optimization of the composition.

The features, structures and effects illustrated in the above embodiments may be included in at least one embodiment of the present invention but are not limited to one embodiment. Further, those skilled in the art will appreciate that various combinations and modifications of the features, structures and effects illustrated in the respective embodiments are possible. Therefore, it will be understood that these combinations and modifications are covered by the scope of the invention.

1. A glass frit composition used for a paste composition for solar cell electrodes comprising:
lead oxide; and
vanadium oxide,
wherein the vanadium oxide is included in an amount of 30 to 70 mol % with respect to 100 mol % in total of the glass frit composition.

2. The glass frit composition according to claim 1, wherein a total amount of the lead oxide and the vanadium oxide is 60 to 100 mol % with respect to 100 mol % in total of the glass frit composition.

3. The glass frit composition according to claim 2, wherein the total amount of the lead oxide and the vanadium oxide is 70 to 100 mol % with respect to 100 mol % in total of the glass frit composition.

4. The glass frit composition according to claim 1, wherein the lead oxide is present in an amount of 30 to 70 mol % with respect to 100 mol % in total of the glass frit composition.

5. The glass frit composition according to claim 4, wherein the lead oxide is present in an amount of 30 to 60 mol % and the vanadium oxide is present in an amount of 40 to 70 mol % with respect to 100 mol % in total of the glass frit composition.

6. The glass frit composition according to claim 1, further comprising alkali metal oxide.

7. The glass frit composition according to claim 6, wherein the alkali metal oxide is present in an amount of 1 to 10 mol % with respect to 100 mol % in total of the glass frit composition.

8. The glass frit composition according to claim 1, wherein the glass frit composition has a glass transition temperature of 200 to 300° C.

9. The glass frit composition according to claim 8, wherein the glass frit composition has a crystallization temperature of 280 to 400° C. which is higher than the glass transition temperature.

10. A paste composition for solar cell electrodes comprising:
a conductive powder;
a glass frit; and
an organic vehicle,
wherein the glass frit comprises lead oxide and vanadium oxide,
wherein the vanadium oxide is included in an amount of 30 to 70 mol % with respect to 100 mol % in total of the glass frit.

11. The paste composition according to claim 10, wherein a total amount of the lead oxide and the vanadium oxide is 60 to 100 mol % with respect to 100 mol % in total of the glass frit.

12. The paste composition according to claim 11, wherein the total amount of the lead oxide and the vanadium oxide is 70 to 100 mol % with respect to 100 mol % in total of the glass frit.

13. The paste composition according to claim 9, wherein the lead oxide is present in an amount of 30 to 70 mol % with respect to 100 mol % in total of the glass frit.

14. The paste composition according to claim 13, wherein the lead oxide is present in an amount of 30 to 60 mol % and the vanadium oxide is present in an amount of 40 to 70 mol %with respect to 100 mol % in total of the glass frit.

15. The paste composition according to claim 1, wherein the glass frit has a glass transition temperature of 200 to 300° C.

16. The paste composition according to claim 15, wherein the glass frit has a crystallization temperature of 280 to 400° C. which is higher than the glass transition temperature.

17. The paste composition according to claim 10, wherein the glass frit is present as a powder having a central particle diameter of 3 μm or less, and
the glass frit is present in an amount of 0.1 to 5.0 parts by weight with respect to 100 parts by weight in total of the paste composition.

18. A solar cell module comprising:
a photoelectric converter;
an electrode connected to the photoelectric converter; and
a ribbon adhered to the electrode,
wherein the electrode comprises a glass frit containing lead oxide and vanadium oxide,
the ribbon comprises lead and tin, and
an adhesion force between the electrode and the ribbon is 1.7N to 6.0N.

19. The solar cell module according to claim 18, wherein the electrode has a contact resistance of 5 to 40 ohm.cm².

20. The solar cell module according to claim 18, wherein the electrode comprises silver as a conductive material.
